(19) United States
(12) Patent Application Publication
(10) Pub. No.: US 2026/0173400 A1
(43) Pub. Date: Jun. 18, 2026

(54) CHIRAL TUNNEL MAGNETIC JUNCTION (CTMJ)

(71) Applicants: International Business Machines Corporation, Armonk, NY (US); Samsung Electronics Co., Ltd., Gyeonggi-Do (KR)

(72) Inventors: See-Hun Yang, Morgan Hill, CA (US); Panagiotis Charilaos Filippou, Fremont, CA (US); Mahesh Samant, San Jose, CA (US); Fnu Ikhtiar, San Jose, CA (US); Jaewoo Jeong, Los Altos, CA (US)

(21) Appl. No.: 18/981,463

(22) Filed: Dec. 14, 2024

(51) Int. Cl. H10B 61/00; H10N 50/01; H10N 50/10; H10N 50/85

(52) U.S. Cl. CPC H10B 61/10; H10N 50/01; H10N 50/10; H10N 50/85

(57) ABSTRACT

A chiral tunnel magnetic junction memory cell includes a chiral reference layer and a free magnetic layer formed from a magnetic alloy. The free magnetic layer has magnetization substantially perpendicular to the free magnetic layer. A tunnel barrier is located between the chiral reference layer and the free magnetic layer. An array of such cells, methods for manufacturing such cells/arrays, and a design structure encoding such cells/array are also provided.

### BACKGROUND

The present invention relates generally to the electrical, electronic and computer arts and, more particularly, to magnetoresistive random-access memory (MRAM).

Current MRAM devices use a magnetic tunnel junction (MTJ) as a storage element. A simple MTJ is a tri-layer structure containing two magnetic layers separated by a tunnel barrier layer. Thus, current MRAMs are three-layer devices employing a magnetic tunnel junction (MTJ). They typically include a reference layer magnet, a tunnel barrier, and a storage or free magnetic layer. Current is passed through the device and the resistance is measured. The resistance changes based on the magnetic orientation of the two magnetic layers, and the relative change in resistance is referred to as the tunnel magnetoresistance (TMR). High TMR is desirable since higher TMR provides a higher ON/OFF ratio. Low switching current is also desirable. The switching current is proportional to the product (Mₛ V Hₖ) where Mₛ is saturation magnetization, V is volume, and Hₖ is anisotropy field.

The MTJ devices are switched using Spin Transfer Torque (referred as STT-MRAM). In STT-MRAM MTJ devices, the magnetic layers have their magnetization perpendicular to the film surface. Perpendicular magnetic anisotropy (PMA) refers to a situation where the magnetic layers have magnetization perpendicular to the film surface. MTJs with magnetic layers having PMA need smaller switching current than for in-plane magnetized layers.

### BRIEF SUMMARY

Principles of the invention provide techniques for a chiral tunnel magnetic junction (CTMJ). In one aspect, an exemplary chiral tunnel magnetic junction memory cell includes: a chiral reference layer; a free magnetic layer formed from a magnetic alloy, the free magnetic layer having magnetization substantially perpendicular to the free magnetic layer; and a tunnel barrier between the chiral reference layer and the free magnetic layer.

In another aspect, a random-access memory array includes: a plurality of bit lines and a plurality of complementary bit lines forming a plurality of bit line-complementary bit line pairs; a plurality of word lines intersecting the plurality of bit line pairs at a plurality of cell locations; and a plurality of chiral tunnel magnetic junction memory cells located at each of the plurality of cell locations. Each of the chiral tunnel magnetic junction memory cells is electrically connected to a corresponding bit line and selectively interconnected to a corresponding one of the complementary bit lines under control of a corresponding one of the word lines. Each of the plurality of chiral tunnel magnetic junction memory cells includes: a chiral reference layer; a free magnetic layer formed from a magnetic alloy, the free magnetic layer having magnetization substantially perpendicular to the free magnetic layer; and a tunnel barrier between the chiral reference layer and the free magnetic layer.

In a further aspect, a method of forming a chiral tunnel magnetic junction memory cell includes providing a substrate with a seed layer thereon; growing a chiral reference layer on the seed layer; forming a tunnel barrier outward of the chiral reference layer; forming a magnetic layer outward of the tunnel barrier; and forming a cap over the magnetic layer.

In still a further aspect, another method of forming a chiral tunnel magnetic junction memory cell includes providing a substrate with a seed layer thereon; growing a magnetic layer on the seed layer; forming a tunnel barrier outward of the magnetic layer; forming a chiral reference layer outward of the tunnel barrier; and forming a cap over the chiral reference layer.

In yet a further aspect, a hardware description language (HDL) design structure is encoded on a machine-readable data storage medium. The HDL design structure includes elements that when processed in a computer-aided design system generate a machine-executable representation of a chiral tunnel magnetic junction memory cell and/or array of such cells, as described.

Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1-4 show aspects of spin filtering from chiral systems, relevant to aspects of the invention;

FIGS. 5-8 depict spin filtering from a magnetic layer, relevant to aspects of the invention;

FIGS. 9-12 depict a chiral tunnel magnetic junction in accordance with aspects of the invention;

FIGS. 13-16 show aspects of STT switching of chiral tunnel magnetic junction state, in accordance with aspects of the invention;

FIGS. 17-19 depict exemplary embodiments with a chiral layer under the tunnel barrier and a magnetic layer on top (top free layer CTMJ stack);

FIGS. 20-22 depict exemplary embodiments with a chiral layer over the tunnel barrier and the magnetic layer underneath (bottom free layer CTMJ stack);

FIG. 23 shows a Heusler compound employed in aspects of the invention;

FIG. 24 shows growth of a Heusler compound on a templating layer according to aspects of the invention;

FIG. 25 shows an array of MRAM cells, according to an aspect of the invention;

FIG. 26 depicts a computing environment according to an embodiment of the present invention (e.g., for implementing a design process such as that of FIG. 27);

FIG. 27 is a flow diagram of a design process used in semiconductor design, manufacture, and/or test;

FIG. 28 is a flow diagram of an exemplary manufacturing process, according to an aspect of the invention; and

FIG. 29 is a flow diagram of another exemplary manufacturing process, according to an aspect of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary chiral tunnel magnetic junction memory cell includes a chiral reference layer 1705, 2005; a free magnetic layer 1709, 2009 formed from a magnetic alloy, the free magnetic layer having magnetization substantially perpendicular to the free magnetic layer; and a tunnel barrier 1707, 2007 between the chiral reference layer and the free magnetic layer.

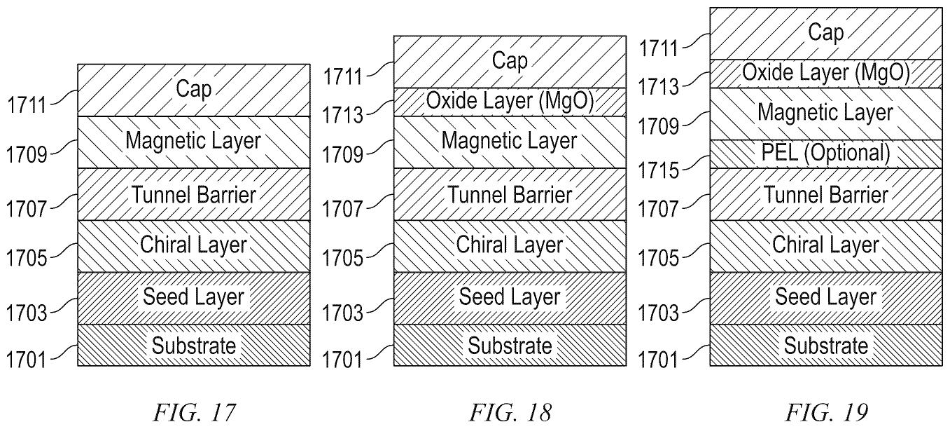

Referring, for example, to FIGS. 17-19, in some cases, the chiral tunnel magnetic junction memory cell further includes a substrate 1701; a cap layer 1711; and a seed layer 1703 overlying the substrate. The chiral reference layer overlies the seed layer, the tunnel barrier is outward of the chiral reference layer, the free magnetic layer is outward of the tunnel barrier, and the cap layer is outward of the free magnetic layer.

In one or more embodiments, the chiral reference layer has a single chirality selected from the group consisting of left-handed and right-handed.

In some cases, the chiral reference layer has a thickness of at least 2 nm.

In some instances, the chiral reference layer contains more than 50% on a volume basis of material having a chirality selected from the group consisting of a left-handed chirality and a right-handed chirality. Refer to the discussion below of the case where the chiral material contains more than 50% (on a volume basis) of material having either left-handed or right-handed chirality.

In one or more embodiments, the chiral reference layer is formed from a material selected from the group consisting of PtAl, BeAu, CoGe, CoSi, FeGe, PdGa, MnGe, RhGe, HfSb, HfSn, ZrSb, MnSi, FeSi, PtGa, RhSi, RuSi, NiSi, CrSi, CrGe, PtMg, ReSi, RhSn, and PdAl.

In some specific cases, the chiral reference layer is formed from a material selected from the group consisting of PtAl and PtGa.

In a non-limiting example, the tunnel barrier includes MgO.

In one or more embodiments, the free magnetic layer includes an alloy of Co, Fe, and B.

In another aspect, the free magnetic layer includes a Heusler compound. In a non-limiting example, the Heusler compound is selected from the group consisting of Mn₃Ge, Mn₃Sn, Mn₃Sb, Mn₂CoSn, Mn₂FeSb, Mn₂CoAl, Mn₂CoGe, Mn₂CoSi, Mn₂CuSi, Co₂CrAl, Co₂CrSi, Co₂MnSb, and Co₂MnSi.

In still another aspect, the free magnetic layer includes a C38 compound.

One or more embodiments further include an oxide layer 1713 between the free magnetic layer and the cap layer.

Some instances further include a polarization enhancement layer 1715 between the free magnetic layer and the tunnel barrier.

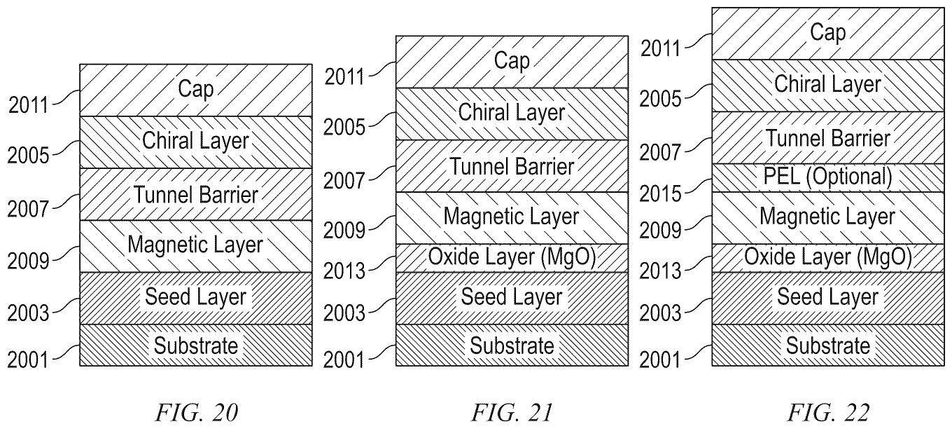

Referring, for example, to FIGS. 20-22, in some cases, the chiral tunnel magnetic junction memory cell further includes a substrate 2001; a cap layer 2011; and a seed layer 2003 overlying the substrate; where the free magnetic layer overlies the seed layer, the tunnel barrier is outward of the free magnetic layer, the chiral reference layer is outward of the tunnel barrier, and the cap layer is outward of the chiral reference layer.

In some cases, the chiral reference layer has a single chirality selected from the group consisting of left-handed and right-handed.

In some instances, the chiral reference layer contains more than 50% on a volume basis of material having a chirality selected from the group consisting of a left-handed chirality and a right-handed chirality. Refer to the discussion below of the case where the chiral material contains more than 50% (on a volume basis) of material having either left-handed or right-handed chirality.

In one or more embodiments, the chiral reference layer is formed from a material selected from the group consisting of PtAl, BeAu, CoGe, CoSi, FeGe, PdGa, MnGe, RhGe, HfSb, HfSn, ZrSb, MnSi, FeSi, PtGa, RhSi, RuSi, NiSi, MnGe, CrSi, CrGe, PtMg, ReSi, RhSn, ZrSb, and PdAl.

In some cases, the free magnetic layer includes a Heusler compound selected from the group consisting of Mn₃Ge, Mn₃Sn, Mn₃Sb, Mn₂CoSn, Mn₂FeSb, Mn₂CoAl, Mn₂CoGe, Mn₂CoSi, Mn₂CuSi, Co₂CrAl, Co₂CrSi, Co₂MnSb, and Co₂MnSi. In some such cases, the seed layer 2003 includes an overlying templating layer including a binary alloy having a CsCl structure, wherein the binary alloy with CsCl structure is represented by A₁₋ₓEₓ, where A is a transition metal element and E is a main group element including at least one of aluminum or gallium, and x is in the range from 0.42 to 0.55.

In other cases, the free magnetic layer includes a C38 compound; in still other cases, free magnetic layer includes an alloy of Co, Fe, and B.

Another aspect includes a random-access memory array as described elsewhere herein (see, e.g., discussion of FIG. 25).

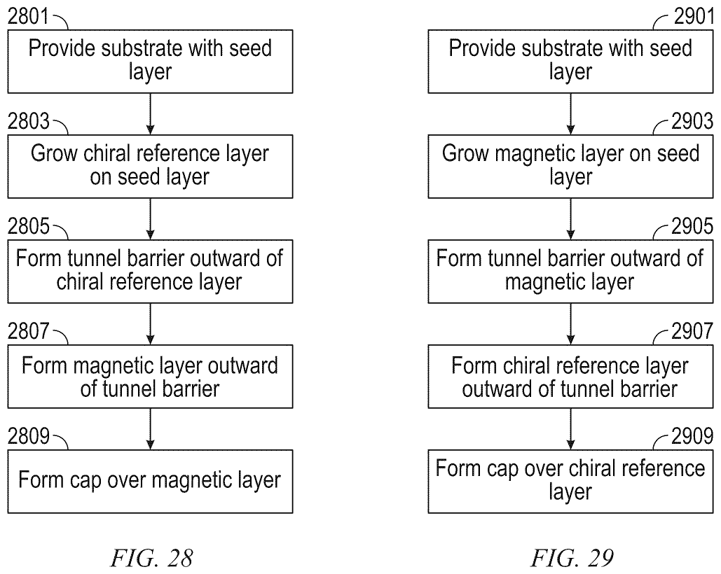

Still another aspect provides methods of forming chiral tunnel magnetic junction memory cells as described elsewhere herein (see, e.g., FIGS. 28 and 29).

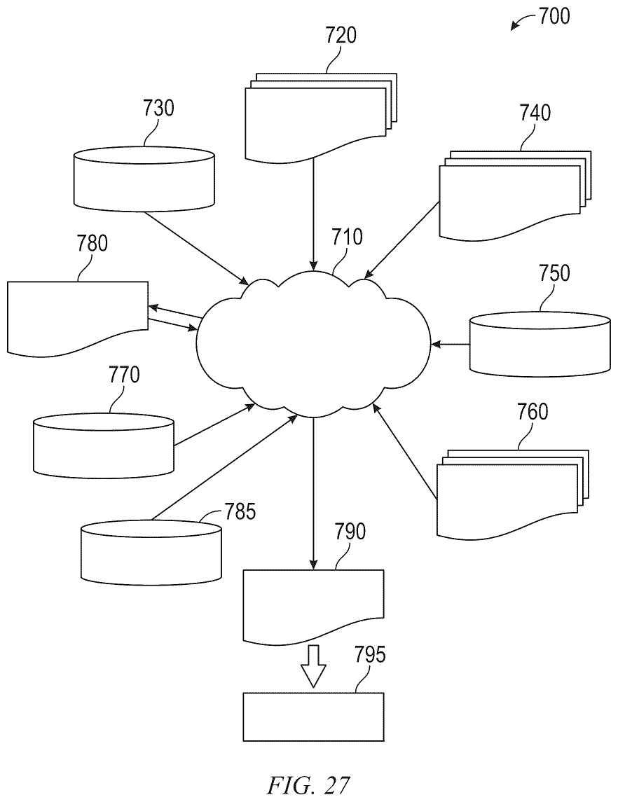

In yet another aspect, a hardware description language (HDL) design structure is encoded on a machine-readable data storage medium. The HDL design structure includes elements that when processed in a computer-aided design system generate a machine-executable representation of a chiral tunnel magnetic junction memory cell and/or a random-access memory array of such cells, as described elsewhere herein (see, e.g., FIG. 27).

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
A chiral tunnel magnetic junction (CTMJ) with reduced switching currents and improved density compared to the prior art, advantageously using storage and tunnel barrier layers developed for conventional MTJs without modifications;
CoFeB layer that is well established as a free layer can be used-typically, the CoFeB layer is an amorphous alloy of CoFe alloy with B, and the B content is typically in the range from approximately 15% to approximately 35%;
Even an ordered compound such as a magnetic Heusler compound or C38 compound can be used as free layer;
The tunnel barrier can be MgO or MgAl₂O₄, and the lattice spacing of an MgAl₂O₄ tunnel barrier can be tuned (engineered) by controlling the Mg—Al composition for better lattice matching with the magnetic layer (e.g., the composition of this tunnel barrier can be represented as Mg_{1-z}Al_{2+(2/3)z}O₄, wherein −0.5<z<0.5);
Spin currents generated from chiral layer are non-reciprocal, implying that spin transfer torque to switch free layers of both directions can be achieved by simply reversing the current flow directions;
Handedness of chiral material is robust and fixed, implying that spin current and spin polarization are determined by current direction only; and
Top Free layer CTMJ facilitates seed layer engineering to optimize chiral layer spin filtering effect.

Advantageously, current STT-MRAM MTJ devices are non-volatile and meet the 10-year data retention criterion. Further, they have high (close to infinite) endurance, as the switching mechanism only requires rotation of electron spin and no change in atomic positions (also, the crystal structure is not affected). Furthermore, the switching currents are too large, and the size of the access transistors determines the device footprint, limiting the chip density, because the access transistor must typically be sized to support the high switching current. In addition, to keep the reference layer fixed, it has a complicated structure.

As used herein, “facilitating” an action includes performing the action, making the action easier, helping to carry the action out, or causing the action to be performed. Thus, by way of example and not limitation, instructions executing on one processor might facilitate an action carried out by a remote processor and/or by semiconductor processing equipment, by sending appropriate data or commands to cause or aid the action to be performed. Where an actor facilitates an action other than by performing the action, the action is nevertheless performed by some entity or combination of entities.

One or more embodiments provide a new device, where the magnetic reference layer within a conventional MTJ is replaced with a layer including chiral materials, known as a chiral tunnel magnetic junction (CTMJ). In one or more embodiments, the switching layer is still a magnetic layer, while the use of a chiral layer simplifies the reference layer.

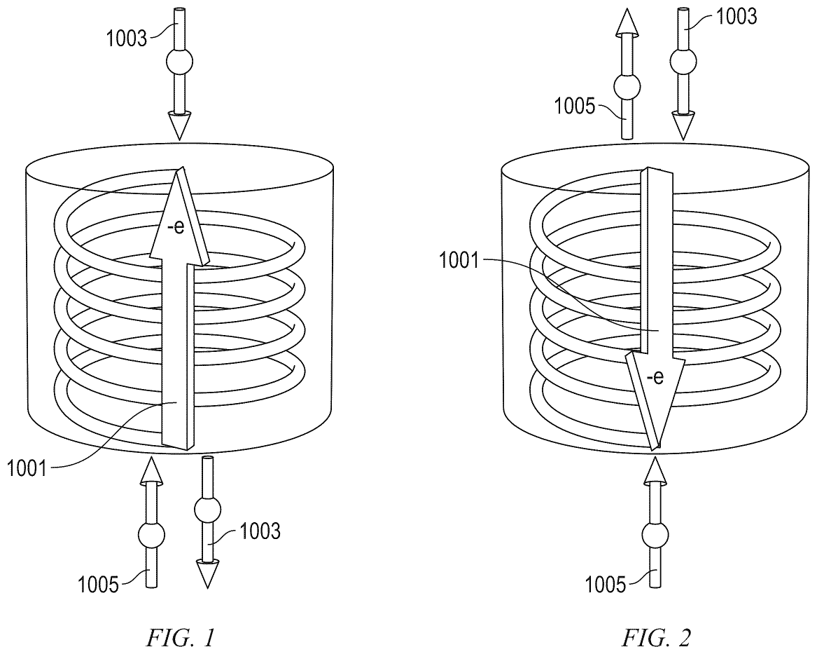

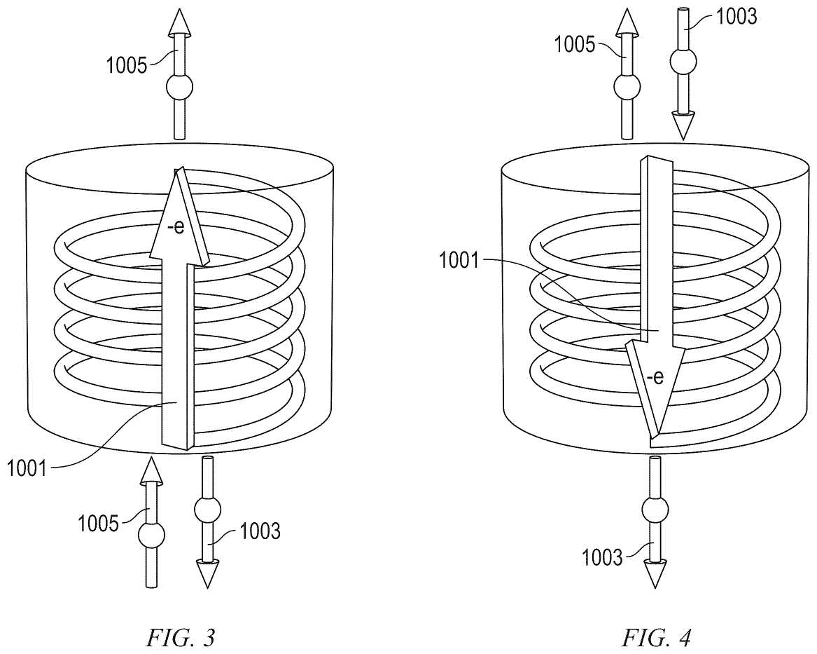

Chirality is the geometric property of a molecule or ion where it cannot be superposed on its mirror image by any combination of rotations, translations, and some conformational changes. FIGS. 1-4 show aspects of spin filtering from chiral systems. FIGS. 1-2 depict left-handed chirality and FIGS. 3-4 depict right-handed chirality. Chiral systems filter electron spins, leading to preferential flow of one spin. The transmitted electron spin direction (up or down) depends on chirality and electron flow direction. Chirality is fixed and determined during material deposition. The conductance of electrons with up and down spin depends on the chirality of the layer. In FIG. 1, electron current, symbolized by bold arrow 1001, flows from bottom to top, and only one spin 1003 (down spin) makes it through; up spin 1005 is blocked. In FIG. 2, the direction of the electron current 1001 is reversed; it flows from top to bottom, and only one spin 1005 (up spin) makes it through; down spin 1003 is blocked. It is worth noting that when the current 1001 is brought in from an external source, it is unpolarized, which is why both spin up and spin down are seen. In FIG. 2, only the up spins 1005 come down.

In FIGS. 3 and 4, for right-handed chirality, depending on the direction of electron flow, either the up spins or the down spins are passed. In FIG. 3, electron current, symbolized by bold arrow 1001, flows from bottom to top, and only one spin 1005 (up spin) makes it through; down spin 1003 is blocked. In FIG. 4, the direction of the electron current 1001 is reversed; it flows from top to bottom, and only one spin 1003 (down spin) makes it through; up spin 1005 is blocked. (Note: the above FIGS. 1-4 assume that spin selection/transmission efficiency, which is a material dependent property, is 100%.)

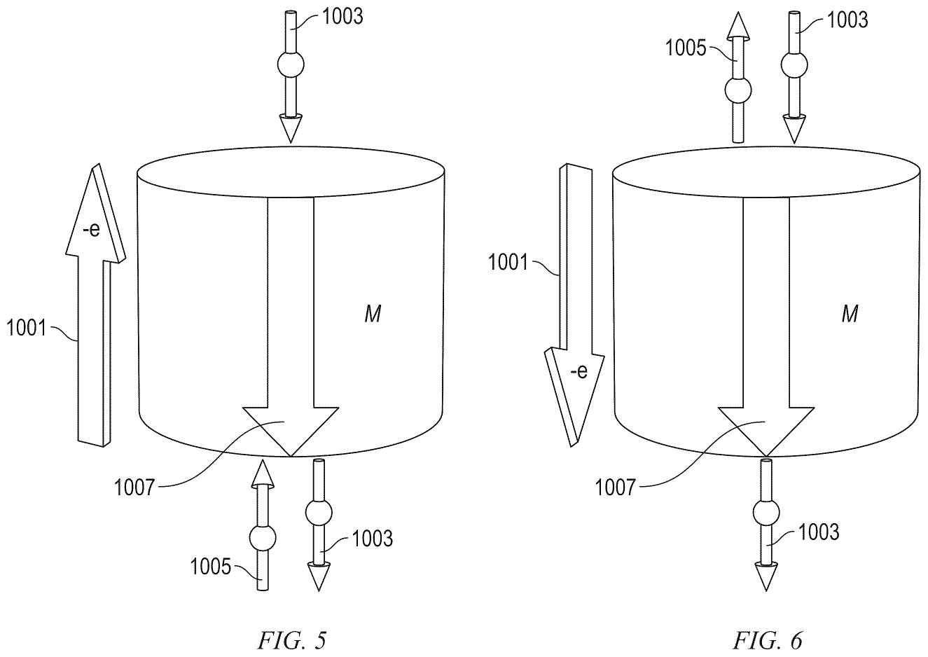

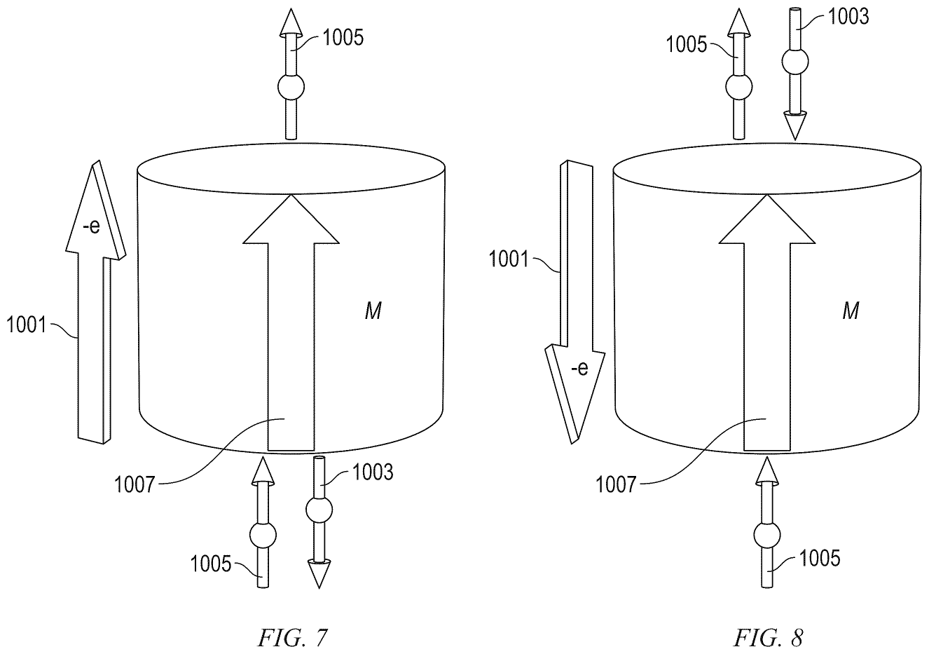

FIGS. 5-8 depict spin filtering from a magnetic layer. In FIGS. 5-6, the magnetization points down while in FIGS. 7-8, the magnetization points up. The magnetic layers filters electron spins, leading to preferential flow of one spin. The transmitted electron spin direction (up or down) depends on the magnetization and the electron flow direction. Unlike chiral systems, the magnetization of a layer can be toggled between the up and down directions. The conductance of electrons with up and down spins depends on the layer magnetization. As in FIGS. 1-4, the incoming current is unpolarized. In FIGS. 5-8, only one spin goes through, depending on the direction of magnetization - only spins parallel to the magnetization direction get through. In FIGS. 5-8, as in FIGS. 1-4, electron current is symbolized by bold arrow 1001, down spin is 1003, and up spin is 1005. The direction of magnetization is indicated by the block arrows 1007. (Note: the above FIGS. 5-8 assume that spin selection efficiency or spin polarization, which is a material dependent property, is 100%.)

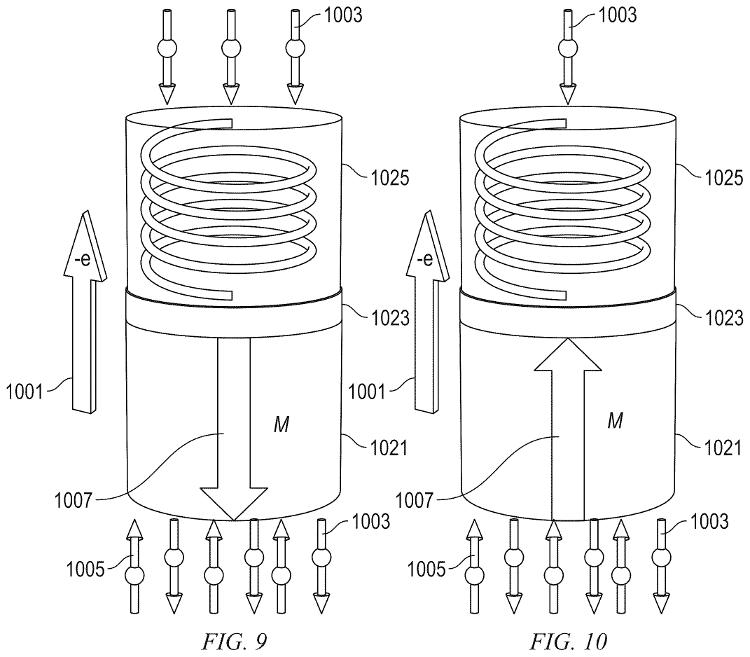

FIGS. 9-12 depict a chiral tunnel magnetic junction in accordance with aspects of the invention. Each device includes a magnetic switching layer 1021, a chiral reference layer 1025, and a tunnel barrier 1023. The exemplary embodiments includes both chiral and magnetic layer spin filtering. The chiral system is robust, since chirality cannot be changed by the flow of electrons. In contrast, if the magnetic layer is designed correctly, its magnetization can be switched using the STT. One or more embodiments flow current in one direction to determine whether the device is in a low resistance state or a high resistance state.

FIGS. 9 and 10 are, respectively, low and high resistance states for left-handed chirality of chiral reference layer 1025. In FIG. 9, the direction of electron current flow is up, as indicated by arrow 1001; the magnetization of switching layer 1021 is down as per block arrow 1007; the incoming current is unpolarized, as indicated by down and up spins 1003, 1005 respectively; and only the down spins 1003 are passed. In FIG. 10, the direction of electron current flow is up, as indicated by arrow 1001; the magnetization of switching layer 1021 is up as per block arrow 1007; the incoming current is unpolarized, as indicated by down and up spins 1003, 1005 respectively; and only the down spins 1003 are passed. The high resistance state is suggested by fewer down spins being passed than in FIG. 9.

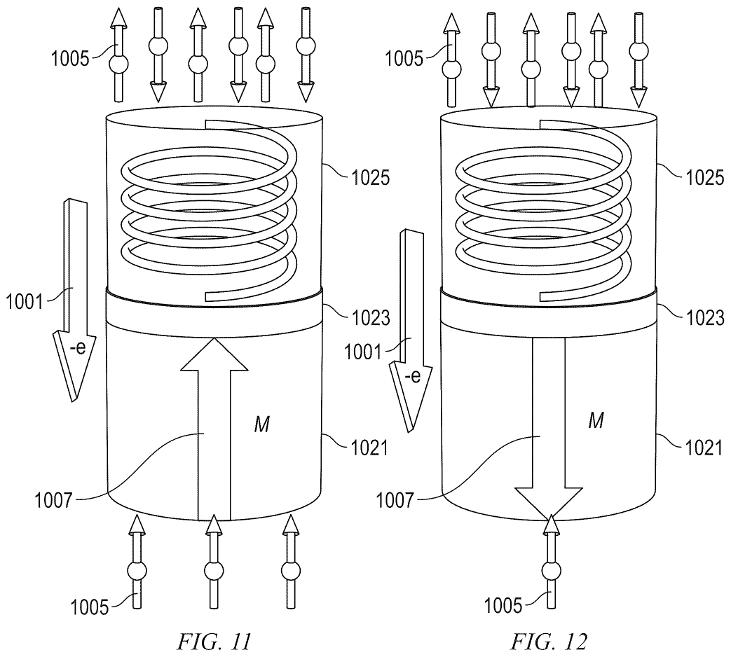

FIGS. 11 and 12 are, respectively, low and high resistance states for right-handed chirality of chiral reference layer 1025. In FIG. 11, the direction of electron current flow is down, as indicated by arrow 1001; the magnetization of switching layer 1021 is up as per block arrow 1007; the incoming current is unpolarized, as indicated by down and up spins 1003, 1005 respectively; and only the up spins 1005 are passed. In FIG. 12, the direction of electron current flow is down, as indicated by arrow 1001; the magnetization of switching layer 1021 is down as per block arrow 1007; the incoming current is unpolarized, as indicated by down and up spins 1003, 1005 respectively; and only the up spins 1005 are passed. The high resistance state is suggested by fewer up spins being passed than in FIG. 11.

The chiral tunnel magnetic junction devices toggle between low and high resistance states by changing the magnetization for either chirality. Conceptually, operation is similar to that of a magnetic tunnel junction (MTJ). The magnetic layer can either be at the bottom or top (i.e. below or above the tunnel barrier); in the non-limiting examples of FIGS. 9-12, the magnetic layers are below the tunnel barrier.

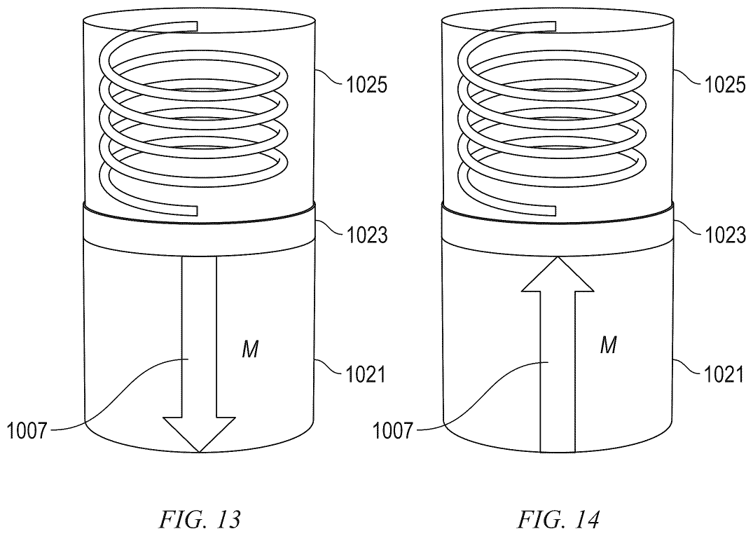

FIGS. 13-16 show aspects of STT switching of chiral tunnel magnetic junction state, in accordance with one or more exemplary embodiments. FIGS. 13 and 14 show left chirality material (fixed layer 1025) on one side of the tunnel barrier 1023 and magnetic material (switching layer 1021) on the other side of the tunnel barrier. FIG. 13 is a low resistance state (magnetization down as per block arrow 1007) and FIG. 14 is a high resistance state (magnetization up as per block arrow 1007). Switching between an up state and a down state is thus shown by the block arrows 1007. To switch from low resistance (FIG. 13) to high resistance (FIG. 14), flow an electron current that exceeds a required threshold from the magnetic layer into the chiral layer. As would be appreciated by the skilled artisan, the required threshold, which when exceeded causes the device to switch its resistance state, can be determined empirically, and will depend on the materials and the geometry (e.g., device sizes, thicknesses, and the like). The down electrons are transmitted through the chiral layer, while the up electrons are reflected back into the magnetic layer. This will switch the magnetic layer magnetization to the up direction as per FIG. 14. On the other hand, to switch from high resistance (FIG. 14) to low resistance (FIG. 13), flow an electron current that exceeds the required threshold from the chiral layer into the magnetic layer. The down electrons are transmitted through the chiral layer, and the down electrons provide spin transfer torque to switch the magnetic layer magnetization to the down direction as per FIG. 13.

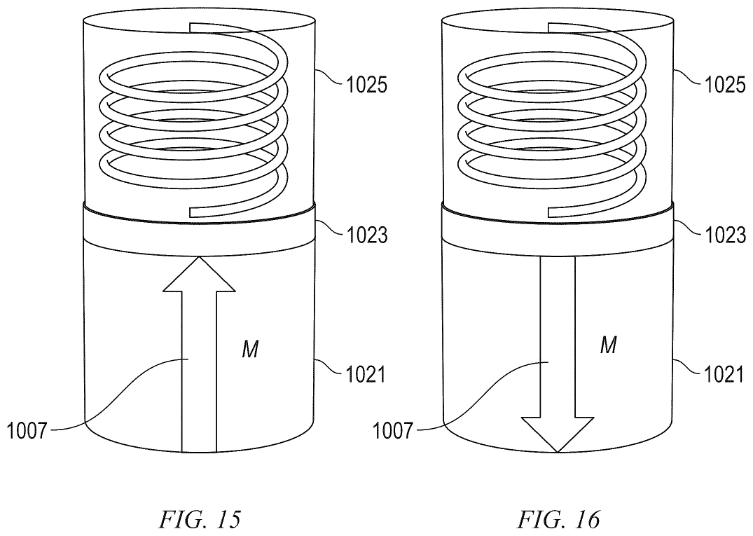

FIGS. 15 and 16 are similar to FIGS. 13 and 14, but for right chirality material. FIG. 15 is a low resistance state (magnetization up as per block arrow 1007) and FIG. 16 is a high resistance state (magnetization down as per block arrow 1007). Switching between an up state and a down state is thus shown by the block arrows 1007. To switch from low resistance (FIG. 15) to high resistance (FIG. 16), flow an electron current that exceeds the required threshold from the magnetic layer into the chiral layer. The up electrons are transmitted through the chiral layer, while the down electrons are reflected back into the magnetic layer. This will switch the magnetic layer magnetization to the down direction as per FIG. 16. On the other hand, to switch from high resistance (FIG. 16) to low resistance (FIG. 15), flow an electron current that exceeds the required threshold from the chiral layer into the magnetic layer. The up electrons are transmitted through the chiral layer, and the up electrons provide spin transfer torque to switch the magnetic layer magnetization to the up direction as per FIG. 15.

In both the left and right chirality cases, the chiral material serves as a reference layer 1025 and also helps to switch the magnetic layer 1021.

Thus, in one or more embodiments, the chiral layer replaces the reference layer in a conventional MTJ - the stack is otherwise similar to a two-terminal MTJ device. The chiral layer can be incorporated in either in the bottom or top layer in the CTMJ, depending on the position of the free layer. A TBL (texture breaking layer), not explicitly shown, can optionally be part of the seed layer, and is useful, for example, in the case where the chiral layer and the magnetic free layer are adjacent to each other which is not the case here. The TBL can be a high spin conductance layer such as NiO, for example.

The chiral material can be chosen, for example, from B20 or C40 structures or other chiral structures (cubic, trigonal, tetragonal, and hexagonal). The chiral material can be chosen, for example, from topological materials with low symmetries.

The B20 structure includes cubic space group 198. Known B20 structures include PtAl, BeAu, CoGe, CoSi, FeGe, PdGa, MnGe, RhGe, HfSb, HfSn, ZrSb, MnSi, FeSi, PtGa, RhSi, RuSi, NiSi, MnGe, CrSi, CrGe, PtMg, ReSi, RhSn, ZrSb, and PdAl.

The C40 structure includes hexagonal space group 180. Known C40 structures include TaGe₂, TaSi₂, VGe₂, HfSn₂, NbGe₂, MoSi₂, VSi₂, WSi₂, CrSi₂, WAl₂, HfSn₂, and NiMg₂.

Possible structures for chiral crystals with chiral symmetrical groups include IrGe₄, Hf5Ir₃, NbGe₂, WAl₂, β-RhSi, Mg₃Ru₂, and YSb₂.

FIGS. 17-19 depict embodiments with a chiral layer under the tunnel barrier and a magnetic layer on top (top free layer CTMJ stack). In FIG. 17, note the substrate 1701, seed layer 1703, chiral layer 1705, tunnel barrier 1707, magnetic layer 1709, and cap 1711. Several options are possible to improve the switching efficiency of the embodiment of FIG. 17. In FIG. 18, use an oxide layer 1713, such as MgO (thin) above the magnetic layer, to reduce damping. In FIG. 19, add a polarization enhancement layer (PEL) 1715 (thin) beneath the magnetic layer to improve the TMR. Thin implies in each case that typically, resistance associated with the layer is ˜10% of that of the MgO layer used within tunnel barrier. It is worth noting that in one or more embodiments, the magnetic layer 1709 has perpendicular magnetic anisotropy, and the substrate 1701 can be, for example, Si with CMOS circuits used for conventional MRAM devices (not shown). In one or more embodiments, the seed layer 1703 is chosen for optimal growth of the chiral layer 1705, the tunnel barrier 1707 can be MgO or MgAl₂O₄, and the cap layer 1711 is a conventional cap used for MTJ devices.

FIGS. 20-22 depict embodiments with a chiral layer over the tunnel barrier and the magnetic layer underneath (bottom free layer CTMJ stack). In FIG. 20, note the substrate 2001, seed layer 2003, magnetic layer 2009, tunnel barrier 2007, chiral layer 2005, and cap 2011. Several options are possible to improve the switching efficiency of the embodiment of FIG. 20. In FIG. 21, use an oxide layer 2013, such as MgO (thin) below the magnetic layer, to reduce damping. In FIG. 22, add a polarization enhancement layer (PEL) 2015 (thin) above the magnetic layer to improve the TMR. It is worth noting that in one or more embodiments, the magnetic layer 2009 has perpendicular magnetic anisotropy, and the substrate 2001 can be, for example, Si with CMOS circuits used for conventional MRAM devices (not shown). In one or more embodiments, the seed layer 2003 is chosen for optimal growth of the magnetic layer 2009, the tunnel barrier 2007 can be MgO or MgAl₂O₄, and the cap layer 2011 is a conventional cap used for MTJ devices. In the case of a Heusler compound for magnetic layer 2009, the seed layer can be, for example, a combination of a nitride layer plus a chemical templating layer. In the case of CoFeB for the magnetic layer 2009, the seed layer can be that which is used in a conventional MTJ and can include, by way of example and not limitation, Ta, Cr, Ru, Mo, W, Ti, Pt, Pd, Cu, Ag, Au, Rh, TiN, WN, TaN etc. or any combination of these materials.

It will thus be appreciated that one or more embodiments provide a structure including a chiral layer 1705, 2005; a tunnel barrier layer 1707, 2007 adjacent to the chiral layer; and a magnetic layer 1709, 2009 whose magnetization is predominantly perpendicular to the layer and is adjacent to the tunnel barrier. The chiral layer, the tunnel barrier, and the magnetic layer form a tri-layer structure.

In one or more embodiments, the chiral material has a single chirality; i.e., either left-handed chirality or right-handed chirality.

In one or more embodiments, the chiral layer has a thickness of at least 2 nm or even at least 3 nm. In one or more embodiments, the chiral layer is a reference layer so its thickness need not necessarily be limited to the ultrathin regime of <3nm. The appropriate thickness will depend on the degree of chirality (i.e., whether the chirality is single or majority of a particular type) and effectiveness of the chiral material to spin filtering.

In one or more embodiments, the chiral material contains more than 50% (on a volume basis) of material having either left-handed or right-handed chirality. Furthermore in this regard, spin filtering efficiency is not zero for a material with mixed chiral phase as long as, say, one chirality (i.e., either left or right handedness) is in the majority. Of course, the spin filtering efficiency is lower than in the case where all of the material has the same chirality, but this can be compensated by appropriate choice of thickness.

In one or more embodiments, the chiral material is selected from the group consisting of PtAl or PtGa.

In one or more embodiments, the tunnel barrier is MgO.

In one or more embodiments, the magnetic layer is an alloy of Co, Fe, and B.

In one or more embodiments, the free layer is a Heusler compound (Mn₃Ge is a non-limiting example of a suitable Heusler compound).

In one or more embodiments, the free layer is a C38 structure (also known as a Cu₂Sb structure) compound (AlMnGe is a non-limiting example of a suitable C38 compound).

In another aspect, an exemplary tri-layer structure includes a chiral layer; a tunnel barrier layer adjacent to the chiral layer; and a magnetic layer adjacent to the tunnel barrier layer, where the magnetic layer's magnetization is predominantly perpendicular to the layer.

In some instances, the chiral material has a B20 or C40 chiral structure or other chiral structure(s).

In one or more embodiments, the chiral material is PtAl or PtGa.

Examples of suitable Heusler compounds include Mn₃Ge, Mn₃Sn, Mn₃Sb, Mn₂CoSn, Mn₂FeSb, Mn₂CoAl, Mn₂CoGe, Mn₂CoSi, Mn₂CuSi, Co₂CrAl, Co₂CrSi, Co₂MnSb, and Co₂MnSi. The Heusler compounds are described in their stoichiometric form here; however, it is possible to vary their stoichiometry over a limited range.

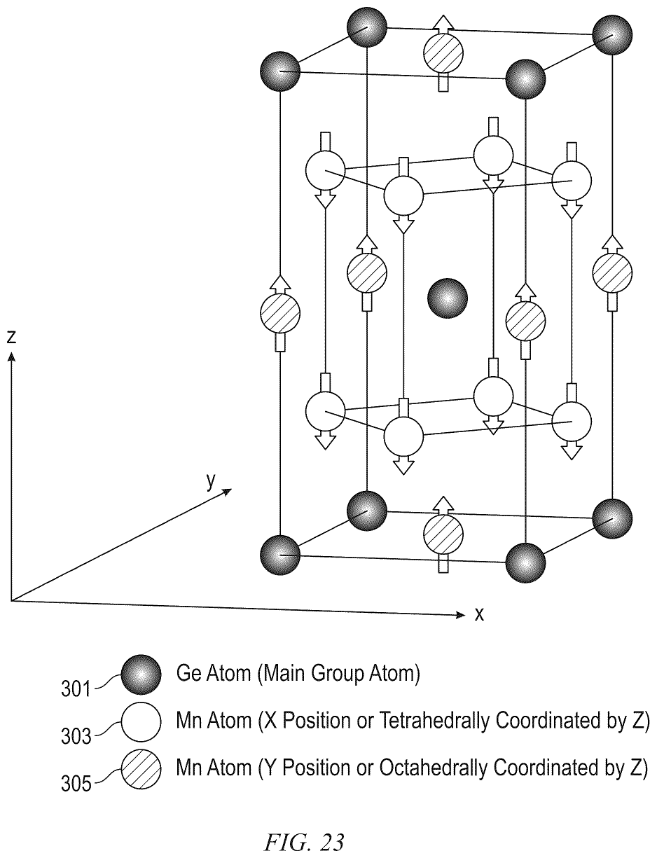

One or more embodiments that employ Heusler compounds make use of a templating layer (in a non-limiting example, a chemical templating layer (CTL)). Referring to FIG. 23 consider now aspects of an exemplary chemical templating layer. A Heusler compound such as Mn₃Ge (alternately Mn₃Sn or Mn₃Sb) includes alternating layers of Mn—Mn and Mn—Ge atoms. In FIG. 23, atoms with shading 301 represent Ge atoms (main group), atoms with shading 303 represent Mn atoms of the X-position in X₂YZ (tetrahedrally coordinated by Z), and atoms with shading 305 represent element Mn atoms of the Y-position in X₂YZ (octahedrally coordinated by Z). Mn is a transition metal and Ge is from the main group of the periodic table. One of the alternating layers contains transition metal atoms 303 only and other contains main group element atoms 301 along with transition metal atoms 305. Thus, a seed layer containing a single element which lattice-matches the in-plane lattice constant does not promote growth of an ordered Heusler compound at low temperatures such as room temperature. An ideal seed layer includes a binary compound of a transition element and a main group element. Moreover, this ideal seed layer also has an alternating layer structure containing these two distinct elements. One layer has only the transition metal. The other layer has only the main group element (the “Z” in X₂YZ is a main group element as well). These binary compounds have a CsCl-like (cesium chloride-like) structure (where each cesium ion is coordinated by eight chloride ions). Exemplary templating layers include CoAl, CoGa, others as discussed elsewhere herein, and the like.

Referring to the crystal structure in FIG. 23, all 3 axes are not the same; dimensions a and b (not labelled in the figure, along the x and y axes) are the same in the depicted example, while dimension c (not labelled in the figure, along the vertical z axis) is different. Note the magnetization arrows going up and down along z. Stretching of crystals in the z direction yields volume anisotropy. Note the alternating layer structure. Use of a seed layer with alternating layer structure containing two distinct elements (one transition metal and other main group element) allows for chemical ordering even during room-temperature growth.

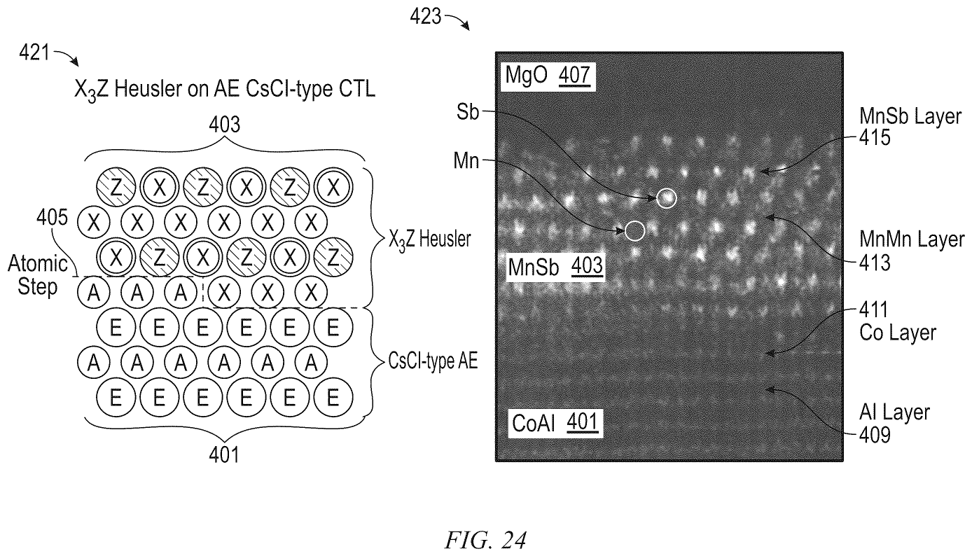

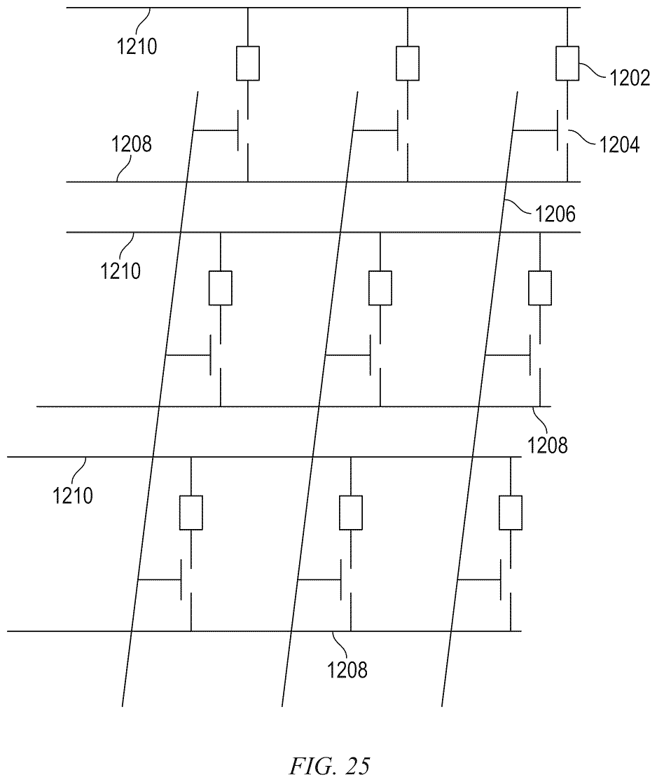

Referring now to FIG. 24, one or more embodiments employ a CsCl-type chemical templating layer (CTL) 401 (CoAl is an example of an excellent CsCl-type CTL) which promotes growth of an ordered Heusler compound even at ultrathin thicknesses and at room temperature. “E” can correspond, for example, to Al and “A” can correspond, for example, to Co. In FIG. 24, view 421 is a schematic while view 423 is a transmission electron microscopy (TEM) image. A Heusler compound such as Mn₃Ge or Mn₃Sn or Mn₃Sb 403 grows epitaxially on top of the CoAl layer 401. In one or more embodiments, the in-plane lattice constant of the ultrathin (<˜25 Å) Heusler compound is similar to that of the CoAl CTL layer. It is possible to strain the Heusler layer to a differing extent with appropriate choice of the CTL layer. We have found that even ternary Heusler compounds can be ordered by the CTL. Note that one or more embodiments use alternative templating layers so that the lattice constant of the Heusler layer more closely matches that of the alternative oxide tunnel barrier.

In the example of FIG. 24, the in-plane lattice constant of the ultrathin Heusler compound is similar to that of the CoAl CTL. It is possible to strain the Heusler to a differing extent with an appropriate choice of CTL. We have found that even ternary Heusler compounds can be ordered by the CTL. As illustrated, the Mn (generally, X) grows on the Al and the Sb (generally, Z) grows on the Co. Note the atomic step 405. The Heusler material can be strained and thus adopts the in-plane lattice constant of the template material. One or more embodiments impose the lattice constant of the templating layer onto the Heusler layer. In view 423, note that CoAl 401 includes Al layers 409 and Co layers 411 and the Mn₃Sb 403 includes MnMn layer 413 and MnSb layer 415. Note the MgO tunnel barrier 407. The three most prominent tetragonal compounds are Mn₃Ge, Mn₃Sn, and Mn₃Sb, and Mn₃Sb has a larger difference in atomic number between Mn and Sb and thus is easier to see in the TEM image 423.

In FIGS. 17-22, the substrate can be silicon with CMOS circuitry such as transistors and access lines permitting selection of individual devices. Other than the novel cells described herein, conventional transistors, access lines, peripheral circuits, and the like can be employed—refer to discussion of FIGS. 25 and 27 below. Heusler layers can be formed, for example, by epitaxial growth on a CTL. The polarization enhancement layer 1715 can be, for example, a thin layer of magnetic material such as cobalt. The cap layer 1711 can include, purely by way of example and not limitation, Mo, W, Ta, Pt, Ru, or a combination thereof.

By way of review, the Heusler layer can be produced via growth on a suitable templating layer. In a templating concept a templating layer is grown and another layer (e.g., Heusler compound) is grown on top of it. Templating essentially means that the layer being grown on the templating layer grows to the lattice constant a of the underlayer/seed layer.

As will be appreciated by the skilled artisan, typically, the magnetization is not fixed, but rather, the magnetization precesses like a spinning top at a non-zero temperature. This can change depending on temperature. In view of this precession, perpendicularity, as used herein, refers to perpendicularity of the time integral/average of the path of the magnetization. The time integral/average of the path of the magnetization could be, for example, “exactly” perpendicular, perpendicular within ±5%, or perpendicular within ±10%.

It should be noted that the Heusler (and other) compounds mentioned herein are indicated by stoichiometric formulas and this does not preclude small variations of up to several % from the nominal values.

Referring now to FIG. 25, an array of MRAM devices 1202 is shown. Each cell 1202 (e.g., embodiment of FIGS. 17-22) is connected to a respective transistor 1204 that controls reading and writing. A word line 1206 provides data to write to the cells 1202, while a bit line 1210 and a bit line complement 1208 read data from the cell 1202. In this manner, a large array of memory devices can be implemented on a single chip. An arbitrarily large number of cells 1202 can be employed, within the limits of the manufacturing processes and design specifications.

Writing data to a cell 1202 includes passing a current through the cell. This current causes the direction of magnetization to switch between a parallel or anti-parallel state, which has the effect of switching between low resistance and high resistance. Because this effect can be used to represent the 1s and 0s of digital information, the cells 1202 can be used as a non-volatile memory. Passing the current in one direction through the cell 1202 causes the magnetization of the free layer 1709, 2009 to be parallel with that of the reference layer 1705, 2005, while passing the current in the other direction through the cell 1202 causes the magnetization of the free layer 1709, 2009 to be antiparallel to that of the reference layer 1705, 2005. Reading the bit stored in a cell 1202 involves applying a voltage (lower than that used for writing information) to the cell 1202 to discover whether the cell offers high resistance to current (“1”) or low resistance (“0”).

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, ion milling, and reactive ion etching (RIE), which are all known techniques to remove select material(s) when forming a semiconductor structure. The Standard Clean 1 (SC1 ) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method, including, but not limited to, the epitaxial growth of the Heusler material(s) (where employed), the growth of both chiral and magnetic layers in the same device, and the structures formed thereby, are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

In another aspect, referring to FIG. 25, a random-access memory array includes a plurality of bit lines 1210 and a plurality of complementary bit lines 1208 forming a plurality of bit line-complementary bit line pairs. A plurality of word lines 1206 intersect the plurality of bit line pairs at a plurality of cell locations. A plurality of chiral tunnel magnetic junction memory cells 1202 are located at each of the plurality of cell locations. Each of the chiral tunnel magnetic junction memory cells 1202 is electrically connected to a corresponding bit line 1210 and selectively interconnected to a corresponding one of the complementary bit lines 1208 under control of a corresponding one of the word lines 1206 (e.g., a respective transistor 1204 is a field effect transistor turned off or on by a signal from word line 1206 applied to its gate, which controls reading and writing and whether the cell is coupled to the complementary bit lines).

Each of the plurality of chiral tunnel magnetic junction memory cells includes a cell as described elsewhere herein with respect to FIGS. 17-22. The cells are connected between the bit lines 1210 and the access FETs 1204. Typically, the capping (“cap”) layer of the devices indicated in FIGS. 17-22 connect to the bit line 1210.

In still another aspect, an exemplary method of operation includes providing an array such as just described, applying signals to the word lines 1206 to cause a first subset of the cells 1202 to store logical ones and a second subset of the cells 1202 to store logical zeroes; and reading the stored logical ones and zeroes via the bit lines 1210 and the complementary bit lines 1208.

In yet another aspect, referring to FIG. 28, an exemplary method of forming a chiral tunnel magnetic junction memory cell (such as in FIGS. 17-19) includes: providing a substrate 1701 with a seed layer 1703, as at 2801; growing a chiral reference layer 1705 on the seed layer, as at 2803; forming a tunnel barrier 1707 outward of the chiral reference layer, as at 2805; forming a magnetic layer 1709 outward of the tunnel barrier, as at 2807; and forming a cap 1711 over the magnetic layer, as at 2809.

In a further aspect, referring to FIG. 29, another exemplary method of forming a chiral tunnel magnetic junction memory cell (such as in FIGS. 20-22) includes: providing a substrate 2001 with a seed layer 2003, as at 2901; growing a magnetic layer 2009 on the seed layer, as at 2903; forming a tunnel barrier 2007 outward of the magnetic layer, as at 2905; forming a chiral reference layer 2005 outward of the tunnel barrier, as at 2907; and forming a cap 2011 over the chiral reference layer, as at 2909.

The methods of both FIG. 28 and FIG. 29 can also include providing and/or forming other elements as discussed, using techniques apparent to the skilled artisan, given the teachings herein. The cells can be integrated into an array by forming a plurality of cells at the same time and interconnecting them with wires, transistors, and peripheral circuitry in a manner apparent to the skilled artisan, given the teachings herein.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from chiral tunnel magnetic junctions (CTMJs) and the like.

An integrated circuit in accordance with aspects of the present inventions can be employed in essentially any application and/or electronic system where chiral tunnel magnetic junctions (CTMJs) and the like would be beneficial. Given the teachings of the present disclosure provided herein, one of ordinary skill in the art will be able to contemplate other implementations and applications of embodiments disclosed herein.

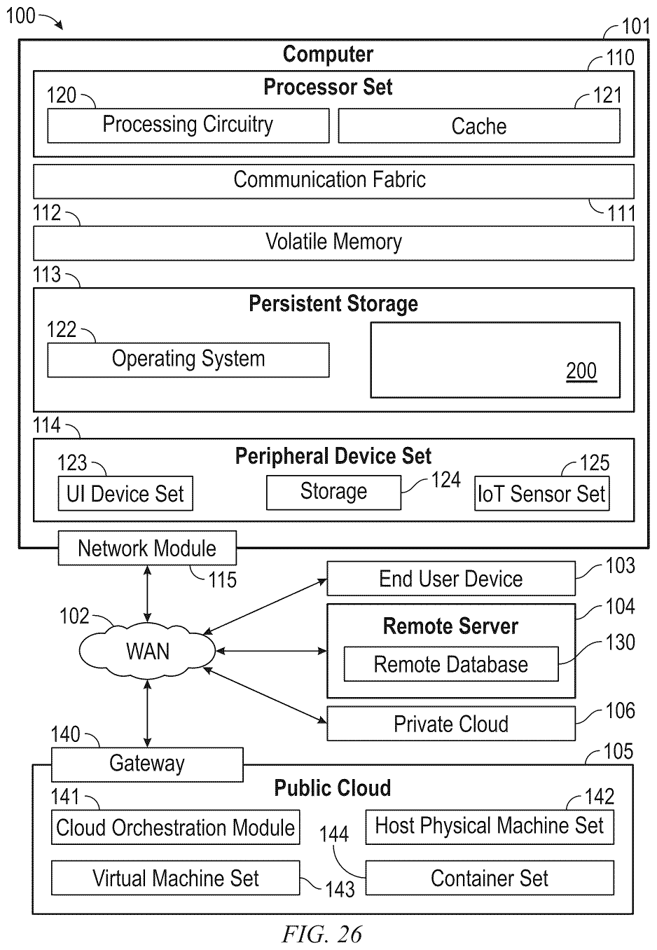

Reference should now be had to FIG. 26, which depicts a computing environment according to an embodiment of the present invention (e.g., for implementing a design process such as that of FIG. 27)

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as a system 200 for semiconductor design and/or control of semiconductor fabrication (see FIG. 27). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 26. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

### Exemplary Design Process Used in Semiconductor Design, Manufacture, and/or Test

One or more embodiments make use of computer-aided semiconductor integrated circuit design simulation, test, layout, and/or manufacture. In this regard, FIG. 27 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 27 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 790 may then proceed to a stage 795 where, for example, design structure 790: proceeds to tape-out, is released to manufacturing, is released to a mask house, is sent to another design house, is sent back to the customer, etc.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A chiral tunnel magnetic junction memory cell, comprising:
a chiral reference layer;
a free magnetic layer formed from a magnetic alloy, the free magnetic layer having magnetization substantially perpendicular to the free magnetic layer; and
a tunnel barrier between the chiral reference layer and the free magnetic layer.

2. The chiral tunnel magnetic junction memory cell of claim 1, further comprising:
a substrate;
a cap layer; and
a seed layer overlying the substrate;
wherein the chiral reference layer overlies the seed layer, the tunnel barrier is outward of the chiral reference layer, the free magnetic layer is outward of the tunnel barrier, and the cap layer is outward of the free magnetic layer.

3. The chiral tunnel magnetic junction memory cell of claim 2, wherein the chiral reference layer has a single chirality selected from the group consisting of left-handed chirality and right-handed chirality.

4. The chiral tunnel magnetic junction memory cell of claim 3, wherein the chiral reference layer has a thickness of at least 2 nm.

5. The chiral tunnel magnetic junction memory cell of claim 3, wherein the chiral reference layer contains more than 50% on a volume basis of material having a chirality selected from the group consisting of a left-handed chirality and a right-handed chirality.

6. The chiral tunnel magnetic junction memory cell of claim 3, wherein the chiral reference layer is formed from a material selected from the group consisting of PtAl, BeAu, CoGe, CoSi, FeGe, PdGa, MnGe, RhGe, HfSb, HfSn, ZrSb, MnSi, FeSi, PtGa, RhSi, RuSi, NiSi, CrSi, CrGe, PtMg, ReSi, RhSn, and PdAl.

7. The chiral tunnel magnetic junction memory cell of claim 3, wherein the chiral reference layer is formed from a material selected from the group consisting of PtAl and PtGa.

8. The chiral tunnel magnetic junction memory cell of claim 7, wherein the tunnel barrier comprises MgO.

9. The chiral tunnel magnetic junction memory cell of claim 8, wherein the free magnetic layer comprises an alloy of Co, Fe, and B.

10. The chiral tunnel magnetic junction memory cell of claim 8, wherein the free magnetic layer comprises a Heusler compound.

11. The chiral tunnel magnetic junction memory cell of claim 10, wherein the Heusler compound is selected from the group consisting of Mn₃Ge, Mn₃Sn, Mn₃Sb, Mn₂CoSn, Mn₂FeSb, Mn₂CoAl, Mn₂CoGe, Mn₂CoSi, Mn₂CuSi, Co₂CrAl, Co₂CrSi, Co₂MnSb, and Co₂MnSi.

12. The chiral tunnel magnetic junction memory cell of claim 8, wherein the free magnetic layer comprises a C38 compound.

13. The chiral tunnel magnetic junction memory cell of claim 2, further comprising an oxide layer between the free magnetic layer and the cap layer.

14. The chiral tunnel magnetic junction memory cell of claim 13, further comprising a polarization enhancement layer between the free magnetic layer and the tunnel barrier.

15. The chiral tunnel magnetic junction memory cell of claim 1, further comprising:
a substrate;
a cap layer; and
a seed layer overlying the substrate;
wherein the free magnetic layer overlies the seed layer, the tunnel barrier is outward of the free magnetic layer, the chiral reference layer is outward of the tunnel barrier, and the cap layer is outward of the chiral reference layer.

16. The chiral tunnel magnetic junction memory cell of claim 15, wherein the chiral reference layer has a single chirality selected from the group consisting of left-handed chirality and right-handed chirality.

17. The chiral tunnel magnetic junction memory cell of claim 16, wherein the chiral reference layer contains more than 50% on a volume basis of material having a chirality selected from the group consisting of a left-handed chirality and a right-handed chirality.

18. The chiral tunnel magnetic junction memory cell of claim 16, wherein the chiral reference layer is formed from a material selected from the group consisting of PtAl, BeAu, CoGe, CoSi, FeGe, PdGa, MnGe, RhGe, HfSb, HfSn, ZrSb, MnSi, FeSi, PtGa, RhSi, RuSi, NiSi, CrSi, CrGe, PtMg, ReSi, RhSn,, and PdAl.

19. The chiral tunnel magnetic junction memory cell of claim 16, wherein the free magnetic layer comprises a Heusler compound selected from the group consisting of Mn₃Ge, Mn₃Sn, Mn₃Sb, Mn₂CoSn, Mn₂FeSb, Mn₂CoAl, Mn₂CoGe, Mn₂CoSi, Mn₂CuSi, Co₂CrAl, Co₂CrSi, Co₂MnSb, and Co₂MnSi.

20. The chiral tunnel magnetic junction memory cell of claim 19, wherein the seed layer includes an overlying templating layer including a binary alloy having a CsCl structure, wherein the binary alloy with CsCl structure is represented by A₁₋ₓEₓ, where A is a transition metal element and E is a main group element including at least one of aluminum or gallium, and x is in the range from 0.42 to 0.55.

21. The chiral tunnel magnetic junction memory cell of claim 16, wherein the free magnetic layer comprises an alloy of Co, Fe, and B.

22. A random-access memory array, comprising:
a plurality of bit lines and a plurality of complementary bit lines forming a plurality of bit line-complementary bit line pairs;
a plurality of word lines intersecting the plurality of bit line pairs at a plurality of cell locations; and
a plurality of chiral tunnel magnetic junction memory cells located at each of the plurality of cell locations, each of the chiral tunnel magnetic junction memory cells being electrically connected to a corresponding bit line and selectively interconnected to a corresponding one of the complementary bit lines under control of a corresponding one of the word lines, each of the plurality of chiral tunnel magnetic junction memory cells comprising:
a chiral reference layer;
a free magnetic layer formed from a magnetic alloy, the free magnetic layer having magnetization substantially perpendicular to the free magnetic layer; and
a tunnel barrier between the chiral reference layer and the free magnetic layer.

23. A method of forming a chiral tunnel magnetic junction memory cell, comprising:
providing a substrate with a seed layer thereon;
growing a chiral reference layer on the seed layer;
forming a tunnel barrier outward of the chiral reference layer;
forming a magnetic layer outward of the tunnel barrier; and
forming a cap over the magnetic layer.

24. A method of forming a chiral tunnel magnetic junction memory cell, comprising:
providing a substrate with a seed layer thereon;
growing a magnetic layer on the seed layer;
forming a tunnel barrier outward of the magnetic layer;
forming a chiral reference layer outward of the tunnel barrier; and
forming a cap over the chiral reference layer.

25. A hardware description language (HDL) design structure encoded on a machine-readable data storage medium, the HDL design structure comprising elements that when processed in a computer-aided design system generates a machine-executable representation of a random-access memory array, wherein the random-access memory array comprises:
a plurality of bit lines and a plurality of complementary bit lines forming a plurality of bit line-complementary bit line pairs;
a plurality of word lines intersecting the plurality of bit line pairs at a plurality of cell locations; and
a plurality of chiral tunnel magnetic junction memory cells located at each of the plurality of cell locations, each of the chiral tunnel magnetic junction memory cells being electrically connected to a corresponding bit line and selectively interconnected to a corresponding one of the complementary bit lines under control of a corresponding one of the word lines, each of the plurality of chiral tunnel magnetic junction memory cells comprising:
a chiral reference layer;
a free magnetic layer formed from a magnetic alloy, the free magnetic layer having magnetization substantially perpendicular to the free magnetic layer; and
a tunnel barrier between the chiral reference layer and the free magnetic layer.
